(19) United States
(12) Patent Application Publication
(10) Pub. No.: US 2024/0404930 A1
(43) Pub. Date: Dec. 5, 2024

(54) PACKAGE STRUCTURE AND RELATED MANUFACTURING METHOD THEREOF

(71) Applicant: STATS CHIPPAC SEMICONDUCTOR (JIANGYIN) CO., LTD., JIANGSU (CN)

(72) Inventors: Jiade Liao, Jiangsu (CN); Jian Xu, Jiangsu (CN); Soo Won Lee, Jiangsu (CN)

(73) Assignee: STATS CHIPPAC SEMICONDUCTOR (JIANGYIN) CO., LTD., JIANGSU (CN)

(21) Appl. No.: 18/679,428

(22) Filed: May 30, 2024

(30) Foreign Application Priority Data
May 31, 2023 (CN) 202310646179.7

(51) Int. Cl. H01L 23/498; H01L 23/00; H01L 23/28; H01L 23/36

(52) U.S. Cl. CPC H01L 23/49811; H01L 23/28; H01L 23/36; H01L 24/16; H01L 24/32; H01L 24/73; H01L 24/92; H01L 24/48; H01L 2224/16227; H01L 2224/32225; H01L 2224/48225; H01L 2224/73204; H01L 2224/92125

(57) ABSTRACT

The present disclosure provides a package structure and a related manufacturing method thereof, wherein a heat dissipation structure surrounding a chip is arranged, and an electrical connection structure is arranged on the outer side of the heat dissipation structure, so that other laminated package components can be electrically connected through a second electrical connection surface of the electrical connection structure to achieve lamination; the heat dissipation structure, the molding layer and the electrical connection structure are fastened through molding the electrical connection structure and the heat dissipation structure by the molding layer, and the molding layer and the electrical connection structure are prevented from warpage by the heat dissipation structure; finally, the package structure has the functions of heat dissipation, lamination and warpage prevention.

### CROSS-REFERENCE TO RELATED APPLICATION

This application claims the priority benefit of China application serial no. 202310646179.7, filed on May 31, 2023. The entirety of the above-mentioned patent application is hereby incorporated by reference herein and made a part of this specification.

### TECHNICAL FIELD

The present disclosure relates to the technical field of chip packaging, and specifically to a package structure and a related manufacturing method thereof.

### BACKGROUND

With the development of chip packaging technology, higher requirements are put forward for the heat dissipation capabilities of chip packaging. In particular, a package structure that can be used for lamination not only needs to improve heat dissipation capabilities, but also needs to have the function of laminating other package components. However, this package structure still has the problem of warpage, and the existing package structure used for lamination cannot combine these three functions. Therefore, it is necessary to provide a package structure that has a strong heat dissipation capability, can be used to stack other package components and can well prevent warpage.

### SUMMARY

The present disclosure provides a package structure and a related manufacturing method therefor, which aims to solve the problem that the existing package structure for stacking cannot have heat dissipation, stacking and warpage prevention at same time.

To achieve the above objective, the present disclosure provides a package structure, which includes:
a substrate;
a chip arranged on a surface of the substrate;
a heat dissipation structure arranged on the surface of the substrate and surrounding the chip;
an electrical connection structure arranged on the surface of the substrate and on an outer side of the heat dissipation structure;
a molding layer encapsulates the electrical connection structure and the heat dissipation structure;
wherein the electrical connection structure includes a first electrical connection surface and a second electrical connection surface, the first electrical connection surface is connected to the substrate, and the molding layer exposes the second electrical connection surface.

Preferably, the electrical connection structure includes the first conductive bumps and an annular interposer;

the first conductive bumps are arranged on the surface of the substrate, the annular interposer is arranged on a surface of the first conductive bumps, and the annular interposer is electrically connected to the substrate through the first conductive bumps; wherein the first electrical connection surface is one side surface that is of the first conductive bumps and that is used to connect to the substrate, and the second electrical connection surface is one side surface that is of the annular interposer and that is exposed to the molding layer.

Preferably, the electrical connection structure includes conductive pillars, and the conductive pillars are electrically connected to the substrate; wherein the first electrical connection surface is one side surface that is of the conductive pillars and that is used to connect to the substrate, and the second electrical connection surface is another side surface that is of the conductive pillars and that is exposed to the molding layer.

Preferably, the electrical connection structure has a height that is consistent with that of the heat dissipation structure.

Preferably, the heat dissipation structure includes an inner surface and an outer surface, the inner surface of the heat dissipation structure faces the chip, and the molding layer exposes at least a part of the outer surface of the heat dissipation structure.

Preferably, a surface that is of the heat dissipation structure and that contacts the molding layer is uneven.

Preferably, the package structure further includes: the second conductive bumps and a filler, wherein the second conductive bumps are arranged between the chip and the substrate, and the filler is filled around the second conductive bumps.

Preferably, the package structure further includes: conductive wires, wherein the conductive wires are connected to the chip and the substrate.

Preferably, the heat dissipation structure is a cover-shaped structure.

Preferably, thermal interface material layers are provided between the heat dissipation structure and the substrate and between the heat dissipation structure and the chip, and the heat dissipation structure is connected to the substrate and the chip through the thermal interface material layers.

Preferably, a surface that is of the heat dissipation structure and that contacts the thermal interface material layer is uneven.

Preferably, solder balls are provided on another side surface that is of the substrate and that is opposite to the side surface on which the chip is provided.

Correspondingly, the present disclosure further provides a manufacturing method for a package structure, which includes:
providing a substrate;
arranging a chip on a surface of the substrate;
forming a heat dissipation structure surrounding the chip on the surface of the substrate;
forming electrical connection structure on the surface of the substrate and around the heat dissipation structure; and
forming a molding layer encapsulates the electrical connection structure and the heat dissipation structure.

Preferably, the arranging a chip on a surface of the substrate further includes:
providing a chip;
arranging the chip on the surface of the substrate through the first conductive bumps; and
filling a filler around the first conductive bumps.

Preferably, the forming a heat dissipation structure surrounding the chip on the surface of the substrate further includes:
forming a thermal interface material layer on the surface of the substrate around the chip and a region that is of the chip surface and that is used to connect a heat dissipation structure; and
providing a heat dissipation structure, and arranging the heat dissipation structure on the surface of the thermal interface material layer.

Preferably, the forming an electrical connection structure on the surface of the substrate and around the heat dissipation structure includes:
forming the first conductive bumps on the surface of the substrate and around the heat dissipation structure; and
providing an annular interposer, and arranging the annular interposer on the surface of the first conductive bumps.

Preferably, the providing an annular interposer includes:
providing an interposer; and
cutting the interposer to form an annular interposer with a hollow part;
wherein the hollow part is used to accommodate the heat dissipation structure.

Preferably, after filling a molding compound encapsulates the electrical connection structure and the heat dissipation structure, the method further includes:
arranging the solder balls on another side surface that is of the substrate and that is opposite to the side surface on which the chip is provided.

The present disclosure has the following beneficial effects: the present disclosure provides a package structure and a corresponding manufacturing method therefor, wherein a heat dissipation structure surrounding a chip is arranged, and an electrical connection structure is arranged on the outer side of the heat dissipation structure, so that other stack package components can be electrically connected through a second electrical connection surface of the electrical connection structure to achieve lamination; the heat dissipation structure, the molding layer and the electrical connection structure are fastened through molding the electrical connection structure and the heat dissipation structure by the molding layer, and the molding layer and the electrical connection structure are driven by the heat dissipation structure to prevent warpage; finally, the package structure has the functions of heat dissipation, lamination and warpage prevention.

### BRIEF DESCRIPTION OF DRAWINGS

FIG. 1 is a schematic diagram of a package structure according to an embodiment of the present disclosure to illustrate technical problems;

FIG. 2 is a schematic diagram of a package structure according to an embodiment of the present disclosure;

FIG. 3 is a split schematic diagram of a package structure according to an embodiment of the present disclosure;

FIG. 4 is a schematic diagram of another embodiment of an electrical connection structure in a package structure according to an embodiment of the present disclosure; and

FIGS. 5 to 9 are schematic diagrams of a preparation process of a package structure according to an embodiment of the present disclosure.

### DETAILED DESCRIPTION OF EMBODIMENTS

The following clearly and completely describes the technical solutions in embodiments of the present disclosure with reference to the accompanying drawings in embodiments of the present disclosure. It is clear that the described embodiments are merely a part rather than all of embodiments of the present disclosure. Based on the embodiments of the present disclosure, all other embodiments obtained by those of ordinary skill in the art without creative effort fall within the protection scope of the present disclosure.

For ease of description, spatially relative terms such as “under”, “below”, “lower”, “above”, “over”, “upper” and the like may be used herein to describe a relationship of one element or feature to other elements or features as illustrated in the accompanying drawings. It should be understood that the spatially relative terms are intended to encompass different orientations of the device in use or operation in addition to the orientation depicted in the accompanying drawings. For example, if the device in the accompanying drawings is turned over, elements described as “below” or “under” other elements or features would then be oriented “above” the other elements or features. Therefore, the term “below” may include both above and below orientations.

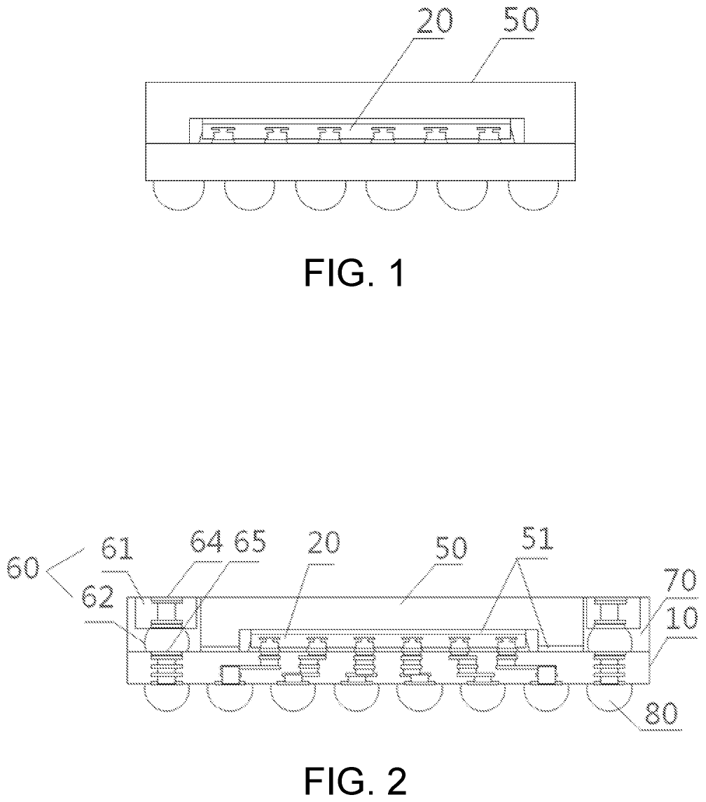

Referring to the package structure shown in FIG. 1, the package structure includes a chip 20 and a heat dissipation structure 50 covering the chip 20. The application scenario of this package structure is limited, and the package structure cannot be used to laminate other package components, and the capability of solving the warpage based on the heat dissipation structure is limited.

Therefore, to solve the above problem, referring to FIG. 2, this embodiment provides a technical solution as follows: a package structure includes:
a substrate 10;
a chip 20 arranged on a surface of the substrate;
a heat dissipation structure 50 arranged on the surface of the substrate and surrounding the chip;
the electrical connection structures 60 arranged on the surface of the substrate and on an outer side of the heat dissipation structure;
a molding layer 70 wrapping the electrical connection structures 10 and the heat dissipation structure 50;
wherein the electrical connection structures 60 include a first electrical connection surface 65 and a second electrical connection surface 64, the first electrical connection surface 65 is connected to the substrate 10, and the molding layer 70 exposes the second electrical connection surface 64.

In some embodiments, the substrate 10 may be a printed circuit board (PCB), a ceramic substrate or the like. In some embodiments, the substrate may also be a redistribution substrate with a circuit pattern, including stacked interconnect layers and an insulation layer surrounding the interconnect layers. In this embodiment, the substrate is a redistribution substrate with a circuit pattern for exemplary explanation, and those skilled in the art can reasonably select a type and model of the substrate 10 based on a model of a packaged product. It is specifically noted here that the scope of protection of the present disclosure should not be unduly limited.

In some embodiments, the chip 20 may be a logic chip or a memory chip. For example, the memory chip may be a DRAM chip, a NAND flash chip, a NOR flash chip, a PRAM chip, a ReRAM chip or an MRAM chip. Optionally, the chip may be a non-memory chip such as an application processor.

In some embodiments, a conductive via is formed in the chip 20, the second conductive bumps are formed between the chip 20 and the substrate 10, and the chip 20 is electrically connected to the substrate 10 through the conductive via and the second conductive bumps. Specifically, the chip 20 and the substrate 10 further include: the second conductive bumps and a filler, wherein the second conductive bumps are arranged between the chip and the substrate, and the filler is filled around the second conductive bumps.

In some embodiments, the chip 20 may also be electrically connected to the substrate 10 by conductive wires. Specifically, the chip 20 and the substrate 10 are further connected to conductive wires, the conductive wires are connected to the chip and the substrate, wherein the conductive wires can be specifically implemented as a gold wire, a silver wire, a copper wire or an aluminum wire.

In some embodiments, the heat dissipation structure 50 includes an inner surface and an outer surface, the inner surface of the heat dissipation structure faces the chip, and the molding layer exposes at least a part of the outer surface of the heat dissipation structure. As shown in FIG. 2, the upper surface of the heat dissipation structure is exposed to the molding layer.

In some embodiments, the electrical connection structure 60 and the heat dissipation structure 50 may be in contact with each other or, as shown in FIG. 2, may be spaced apart to facilitate mounting of the electrical connection structure.

In some embodiments, the electrical connection structure has a height that is consistent with that of the heat dissipation structure, so as to expose at least a part of the outer surface of the heat dissipation structure and the second electrical connection surface of the electrical connection structure. As shown in FIG. 2, when the height of the electrical connection structure is consistent with the height of the heat dissipation structure, the upper surface of the outer surface of the heat dissipation structure is exposed to the molding layer.

In some embodiments, as shown in FIG. 2, the heat dissipation structure 50 is a cover-shaped structure surrounding the chip. Specifically, the heat dissipation structure 50 may be an annular cover-shaped structure or a square cover-shaped structure.

In some embodiments, the heat dissipation structure may be a heat dissipation plate with a preformed cover-shaped structure. However, in other embodiments, the heat dissipation structure may also be formed by a heat dissipation plate and other structures to surround the chip.

In some embodiments, the heat dissipation plate may be made of an alloy material with a heat dissipation function, such as a copper-nickel alloy material.

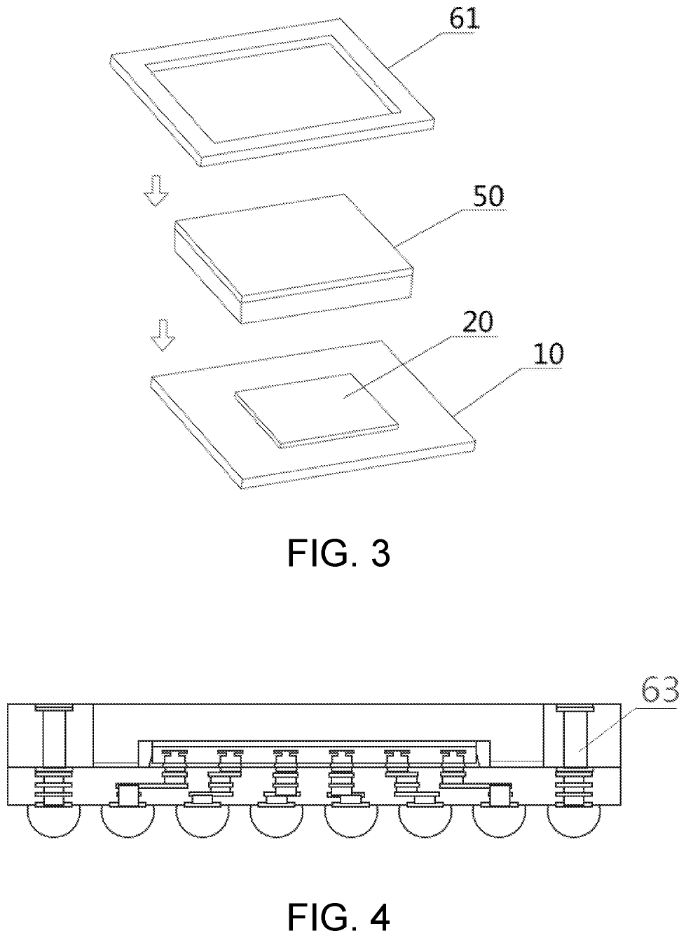

As shown in FIG. 3, when the heat dissipation structure 50 is a heat dissipation plate with a preformed cover-shaped structure, the chip 20 is first arranged on the surface of the substrate 10, then the preformed heat dissipation structure 30 is covered on the chip 20 in the direction of the arrow, and then the preformed annular interposer is arranged around the chip on the surface of the substrate in the direction of the arrow.

In some embodiments, the heat dissipation structure 50 may be connected to the chip or may not be connected to the chip.

In some embodiments, when the heat dissipation structure 50 is connected to the chip, thermal interface material layers 51 may be arranged between the heat dissipation structure and the substrate and between the heat dissipation structure and the chip, and the heat dissipation structure is connected to the substrate and the chip through the thermal interface material layers 51.

The thermal interface material layer may include one or more of silicone grease and silica gel heat dissipation pads, a phase change material phase change metal sheet, a thermal conductive adhesive and the like.

In the illustrated embodiment, the package structure may be electrically connected to other package components laminated thereon through the second electrical connection surface of the electrical connection structure, so as to have a function of laminating other package components, wherein the other package components may be a chip, a redistribution layer and the like.

In the illustrated embodiment, since the heat dissipation structure has certain hardness, the warpage caused by the substrate can be limited to a certain extent by connecting the heat dissipation structure to the substrate in the embodiment. In addition, the molding layer wrapping the heat dissipation structure and the electrical connection structure is arranged, so that the molding layer connected to the heat dissipation structure can be fastened through the hardness effect of the heat dissipation structure; and the electrical connection structure connected to the molding layer is fastened through the molding layer, so that these structures can be limited, and the warpage problem is solved.

In some embodiments, a surface that is of the heat dissipation structure 50 and that contacts the thermal interface material layer 51 is uneven, so that the contact area between the heat dissipation structure and the thermal interface material layer is increased, and the connection strength between the heat dissipation structure and the thermal interface material layer is improved, so that the warpage prevention capability is further improved.

In some embodiments, as shown in FIG. 2, the electrical connection structure 60 includes an annular interposer 61 and the first conductive bumps 62, the first conductive bumps are arranged on the surface of the substrate, the annular interposer is arranged on a surface of the first conductive bumps, and the annular interposer 61 is electrically connected to the substrate 10 through the first conductive bumps 62. As shown in FIG. 3, to allow the annular interposer to be positioned outside the heat dissipation structure, the annular interposer 61 has a hollow part for accommodating the heat dissipation structure. In this case, the first electrical connection surface 65 is one side surface that is of the first conductive bumps and that is used to connect to the substrate, and the second electrical connection surface 64 is one side surface that is of the annular interposer and that is exposed to the molding layer.

In some embodiments, a plurality of first conductive bumps may be provided and arranged on the surface of the substrate around the chip, and one annular interposer may be provided and bonded on the surface of the first conductive bumps.

The annular interposer 61 is a preformed interconnection structure and is obtained by cutting a middle part of the interposer, wherein a size of the cut area is determined based on a size of the area of the heat dissipation structure, so that the hollow part of the annular interposer formed after cutting can accommodate the heat dissipation structure. The interposer is similar to a redistribution substrate structure with circuit patterns, which is an interconnect structure, including several via structures with fine pitches, such as through-silicon vias (TSVs); and the interposer is configured to electrically connect two or more electronic devices (such as chips, redistribution layers or other package components) disposed on two opposing surfaces of the interconnect structure.

In some embodiments, as shown in FIG. 4, the electrical connection structure includes conductive pillars 63, and the conductive pillars 63 are electrically connected to the substrate 10. In this case, the first electrical connection surface 65 is one side surface that is of the conductive pillars and that is used to connect to the substrate, and the second electrical connection surface 64 is one side surface that is of the conductive pillars and that is exposed to the molding layer.

In some embodiments, a plurality of conductive pillars 63 are provided and arranged on the surface of the substrate around the chip.

In some embodiments, the molding layer 70 is arranged on the surface of the substrate 10 and wraps the electrical connection structure and the heat dissipation structure.

In some embodiments, a surface that is of the heat dissipation structure and that contacts the molding layer is uneven, so that the contact area between the heat dissipation structure and the molding layer is increased, and the connection strength between the heat dissipation structure and the molding layer is improved, so that the warpage prevention capability is further improved.

In some embodiments, as shown in FIG. 2, the solder balls 80 are provided on another side surface that is of the substrate and that is opposite to the side surface on which the chip is provided.

In some embodiments, due to various factors such as the material from which the substrate is made, different types and degrees of warpage are induced, wherein the warpage types can include a warpage type of upward bending of the middle part of the substrate and downward bending of the edge of the substrate and a warpage type such as downward bending of the middle part of the substrate and upward bending of the edge of the substrate, so that the contact position between the heat dissipation structure and the substrate, the size of the entire heat dissipation structure and the size of the entire electrical connection structure can be adjusted according to the warpage types, and the size of the contact area between the heat dissipation structure and the substrate is used solve the problem of different warpage degrees. The contact position of the heat dissipation structure and the substrate can be arranged at a position that is close to the edge or a position close to the middle and that is of the surface of the substrate, so that the contact position of the electrical connection structure and the substrate is adjusted.

The size of the entire heat dissipation structure and/or the size of the contact area between the heat dissipation structure and the substrate can be adjusted based on different warpage degrees. For example, when the warpage degree is large, the entire heat dissipation structure and/or the contact area between the heat dissipation structure and the substrate can be increased.

In some embodiments, a manufacturing method for a package structure is further provided, which includes:
providing a substrate;
arranging a chip on a surface of the substrate;
forming a heat dissipation structure surrounding the chip on the surface of the substrate;
arranging an electrical connection structure on the surface of the substrate and around the heat dissipation structure; and
forming a molding layer encapsulates the electrical connection structure and the heat dissipation structure.

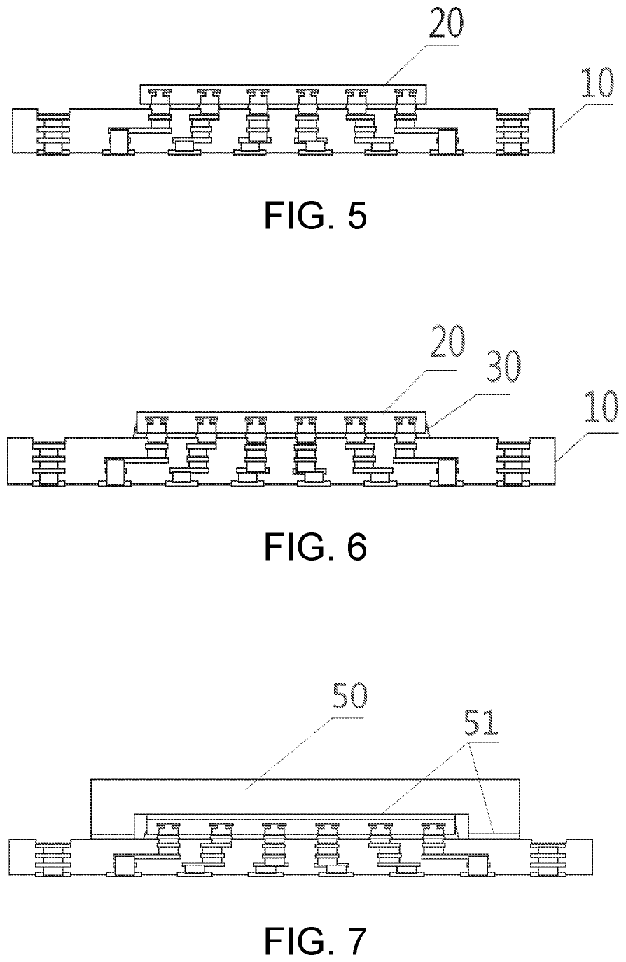

In some embodiments, referring to FIG. 5, the substrate 10 provided can be seen.

In some embodiments, the arranging a chip on a surface of the substrate includes:
providing a chip 20, and arranging the chip 20 on the surface of the substrate 10 through the second conductive bumps, as shown in FIG. 5; and
filling a filler 30 around the second conductive bumps, as shown in FIG. 6.

In some embodiments, the arranging a chip on a surface of the substrate includes:
providing a chip, adhering the chip to the surface of the substrate through an adhesive layer, and bonding wires on the surface of the chip and the surface of the substrate around the chip so as to connect the chip and the substrate through conductive wires.

In some embodiments, referring to FIG. 7, the heat dissipation structure 50 is a prefabricated cover-shaped structure.

In some embodiments, when the heat dissipation structure 50 is a prefabricated cover-shaped structure, the forming a heat dissipation structure surrounding the chip on the surface of the substrate includes:
forming a thermal interface material layer 51 on the substrate surface around the chip and a region that is of the chip surface and that is used to connect a heat dissipation structure, as shown in FIG. 7; and providing a heat dissipation structure 50, and arranging the heat dissipation structure 50 on the surface of the thermal interface material layer 51.

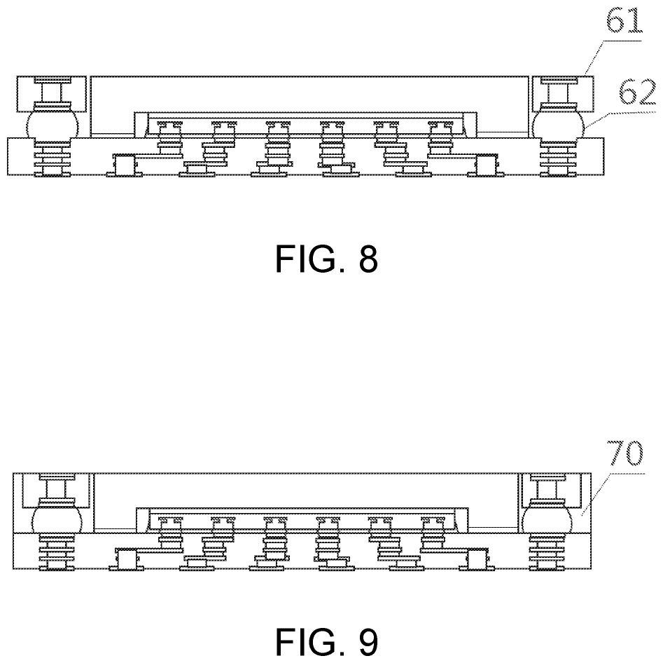

In some embodiments, as shown in FIG. 8, when the electrical connection structure includes the first conductive bumps 62 and the annular interposer 61, the arranging an electrical connection structure on the surface of the substrate and around the heat dissipation structure includes:
forming the first conductive bumps 62 on the surface of the substrate and around the heat dissipation structure; and providing an annular interposer 61, and arranging the annular interposer 61 on the surface of the first conductive bumps 62, so as to form an electrical connection structure including the first conductive bumps 62 and the annular interposer 61, as shown in FIG. 8, wherein the electrical connection structure is formed around the chip; and
then, forming a molding layer 70 encapsulates the electrical connection structure and the heat dissipation structure on the surface of the substrate, as shown in FIG. 9.

In some embodiments, after forming a molding layer 70 wrapping the electrical connection structure and the heat dissipation structure, the method further includes:
arranging solder balls on another side surface that is of the substrate and that is opposite to the side surface on which the chip is provided, so as to form the solder ball 80 as shown in FIG. 2.

The present disclosure has been described with reference to the preferred embodiment, which is not intended to be limited thereto. Those skilled in the art can make possible variations and modifications to the present disclosure using the disclosed methods and technical contents without departing from the spirit and scope of the present disclosure; and therefore, any simple modifications, equivalent changes and modifications made to the above embodiments according to the technical spirit of the present disclosure without departing from the content of the technical solutions of the present disclosure shall fall within the protection scope of the technical solutions of the present disclosure.

What is claimed is:

1. A package structure, comprising:
a substrate;
a chip arranged on a surface of the substrate;
a heat dissipation structure arranged on the surface of the substrate and surrounding the chip;
an electrical connection structure arranged on the surface of the substrate and on an outer side of the heat dissipation structure; and
a molding layer encapsulating the electrical connection structure and the heat dissipation structure;
wherein the electrical connection structure comprises a first electrical connection surface and a second electrical connection surface, the first electrical connection surface is connected to the substrate, and the molding layer exposes the second electrical connection surface.

2. The package structure according to claim 1, wherein the electrical connection structure comprises first conductive bumps and an annular interposer; and
wherein the first conductive bumps are arranged on the surface of the substrate, the annular interposer is arranged on a surface of the first conductive bumps, and the annular interposer is electrically connected to the substrate through the first conductive bumps; wherein the first electrical connection surface is a side surface of the first conductive bumps used to connect to the substrate, and the second electrical connection surface is a side surface of the annular interposer exposed to the molding layer.

3. The package structure according to claim 1, wherein the electrical connection structure comprises conductive pillars, and the conductive pillars are electrically connected to the substrate; wherein the first electrical connection surface is a side surface the conductive pillars used to connect to the substrate, and the second electrical connection surface is a side surface of the conductive pillars exposed to the molding layer.

4. The package structure according to claim 1, wherein the electrical connection structure has a height that is consistent with that of the heat dissipation structure.

5. The package structure according to claim 1, wherein the heat dissipation structure comprises an inner surface and an outer surface, the inner surface of the heat dissipation structure faces the chip, and the molding layer exposes at least a part of the outer surface of the heat dissipation structure.

6. The package structure according to claim 1, wherein a surface in contact between the heat dissipation structure and the molding layer is uneven.

7. The package structure according to claim 1, further comprising second conductive bumps and a filler, wherein the second conductive bumps are arranged between the chip and the substrate, and the filler is filled around the second conductive bumps.

8. The package structure according to claim 1, further comprising conductive wires, wherein the conductive wires are connected to the chip and the substrate.

9. The package structure according to claim 1, wherein the heat dissipation structure is a cover-shaped structure.

10. The package structure according to claim 1, wherein thermal interface material layers are provided between the heat dissipation structure and the substrate and between the heat dissipation structure and the chip, and the heat dissipation structure is connected to the substrate and the chip through the thermal interface material layers.

11. The package structure according to claim 10, wherein a surface in contact between the heat dissipation structure and the thermal interface material layer is uneven.

12. The package structure according to claim 1, wherein solder balls are provided on another side surface of the substrate opposite to the side surface on which the chip is provided.

13. A manufacturing method for a package structure, comprising:
providing a substrate;
arranging a chip on a surface of the substrate;
forming a heat dissipation structure surrounding the chip on the surface of the substrate;
forming an electrical connection structure on the surface of the substrate and around the heat dissipation structure; and
forming a molding layer encapsulating the electrical connection structure and the heat dissipation structure.

14. The manufacturing method for the package structure according to claim 13, wherein the arranging the chip on the surface of the substrate comprises:
providing the chip;
arranging the chip on the surface of the substrate through first conductive bumps; and
filling a filler around the first conductive bumps.

15. The manufacturing method for the package structure according to claim 13, wherein the forming the heat dissipation structure surrounding the chip on the surface of the substrate comprises:
forming a thermal interface material layer on the surface of the substrate around the chip and a region of the chip surface used to connect the heat dissipation structure; and
providing the heat dissipation structure, and arranging the heat dissipation structure on the surface of the thermal interface material layer.

16. The manufacturing method for the package structure according to claim 13, wherein the forming the electrical connection structure on the surface of the substrate and around the heat dissipation structure comprises:
forming first conductive bumps on the surface of the substrate and around the heat dissipation structure; and
providing an annular interposer, and arranging the annular interposer on the surface of the first conductive bumps.

17. The manufacturing method for the package structure according to claim 16, wherein the providing the annular interposer comprises:
providing an interposer; and
cutting the interposer to form the annular interposer with a hollow part;
wherein the hollow part is used to accommodate the heat dissipation structure.

18. The manufacturing method for the package structure according to claim 13, after forming the molding layer encapsulating the electrical connection structure and the heat dissipation structure, further comprising:
arranging solder balls on another side surface of the substrate opposite to the side surface on which the chip is provided.
